(19) United States
(12) Patent Application Publication
(10) Pub. No.: US 2025/0140677 A1
(43) Pub. Date: May 1, 2025

(54) SEMICONDUCTOR PACKAGE

(71) Applicant: Samsung Electronics Co., Ltd., Suwon-si (KR)

(72) Inventors: Min Jeong SHIN, Suwon-si (KR); Duck Gyu KIM, Suwon-si (KR)

(21) Appl. No.: 18/739,665

(22) Filed: Jun. 11, 2024

(30) Foreign Application Priority Data
Nov. 1, 2023 (KR) 10-2023-0148711

(51) Int. Cl. H01L 23/498; H01L 23/00; H01L 25/10

(52) U.S. Cl. CPC H01L 23/49838; H01L 23/49822; H01L 24/04; H01L 24/08; H01L 24/16; H01L 24/32; H01L 24/73; H01L 25/105; H01L 2224/0401; H01L 2224/08225; H01L 2224/16225; H01L 2224/32225; H01L 2224/48; H01L 2224/48225; H01L 2224/73204; H01L 2225/1058; H01L 2924/1815

(57) ABSTRACT

A semiconductor package includes a redistribution substrate including a first surface and a second surface, which are opposite to each other in a first direction, a semiconductor chip mounted on the first surface of the redistribution substrate, a redistribution pattern in the redistribution substrate and electrically connected to the semiconductor chip, a metal pattern electrically connected to the redistribution pattern, including a third surface and a fourth surface, which are opposite to each other in the first direction, and a connection terminal on the second surface of the redistribution substrate and being in contact with the fourth surface of the metal pattern, wherein at least a portion of the redistribution pattern is in contact with sidewalls of the metal pattern, wherein the third surface faces the semiconductor chip and is not in contact with the redistribution pattern, and wherein the fourth surface does not overlap the second surface in the first direction.

### CROSS-REFERENCE TO RELATED APPLICATION

This application claims priority from Korean Patent Application No. 10-2023-0148711, filed Nov. 1, 2023, in the Korean Intellectual Property Office and all the benefits accruing therefrom under 35 U.S.C. 119, the contents of which are herein incorporated by reference in its entirety.

### BACKGROUND

### Technical Field

The present disclosure relates to a semiconductor package, and more particularly, to a semiconductor package that improves reliability by forming an under bump metallurgy (UBM) prior to a redistribution layer (RDL) in a redistribution substrate.

### Description of the Related Art

A semiconductor package implements an integrated circuit chip in a form suitable for use in electronic products. It is general practice that the semiconductor package packages semiconductor chips on a printed circuit board and electrically connects them by using bonding wires or bumps. With the development of the electronics industry, various studies for improving reliability of the semiconductor package and miniaturizing the semiconductor package have been undertaken.

Meanwhile, when damage is incurred at an edge of an under bump metallurgy (UBM) due to the difference in physical properties between a photoimageable dielectric (PID) material and the UBM, the performance and reliability of the package may be degraded.

### SUMMARY

Embodiments of the present disclosure may provide a semiconductor package that may improve the performance and reliability of a product.

The embodiments of the present disclosure are not limited to those mentioned above and additional embodiments of the present disclosure, which are not mentioned herein, will be clearly understood by those skilled in the art from the following description of the present disclosure.

According to an aspect of the present disclosure, there is provided a semiconductor package comprising, a redistribution substrate including a first surface and a second surface, which are opposite to each other in a first direction, a semiconductor chip mounted on the first surface of the redistribution substrate, a redistribution pattern in the redistribution substrate and electrically connected to the semiconductor chip, a metal pattern electrically connected to the redistribution pattern, including a third surface and a fourth surface, which are opposite to each other in the first direction, and a connection terminal on the second surface of the redistribution substrate and being in contact with the fourth surface of the metal pattern, wherein at least a portion of the redistribution pattern is in contact with sidewalls of the metal pattern, wherein the third surface faces the semiconductor chip and is not in contact with the redistribution pattern, and wherein the fourth surface does not overlap the second surface in the first direction.

According to another aspect of the present disclosure, there is provided a semiconductor package comprising a redistribution substrate including a first insulating layer and a second insulating layer, which are stacked in a first direction, the redistribution substrate including a first surface and a second surface, which are opposite to each other in the first direction, a semiconductor chip mounted on the first surface of the redistribution substrate, a redistribution pattern in the redistribution substrate, a metal pattern at least partially in the first insulating layer and electrically connected to the redistribution pattern, and a connection terminal on the first surface of the redistribution substrate, having one end electrically connected to the metal pattern and the other end electrically connected to the semiconductor chip, wherein at least a portion of the redistribution pattern is in contact with sidewalls of the metal pattern, wherein the metal pattern is not in contact with the first surface, wherein a portion of the redistribution pattern overlaps the first insulating layer in a second direction crossing the first direction, and another portion of the redistribution pattern is on the first insulating layer, and wherein a portion of the metal pattern is in contact with the second insulating layer.

According to another aspect of the present disclosure, there is provided a semiconductor package comprising, a semiconductor chip including a chip pad, a first insulating layer including a trench, such that the chip pad is free of the first insulating layer, on the semiconductor chip, a second insulating layer on the first insulating layer, a metal pattern that passes through the second insulating layer and is in contact with the first insulating layer, a redistribution pattern that extends along an upper surface of the first insulating layer, a profile of the metal pattern, and a profile of the trench and is electrically connected to the chip pad, and a connection terminal, which is electrically connected to the metal pattern, wherein the metal pattern protrudes from an upper surface of the second insulating layer.

### BRIEF DESCRIPTION OF THE DRAWINGS

The above and other aspects and features of the present disclosure will become more apparent by describing in detail example embodiments thereof with reference to the attached drawings, in which:

FIG. 1 is an example plan view illustrating a semiconductor package according to some embodiments of the present disclosure.

FIG. 2 is an example cross-sectional view taken along line A-A of FIG. 1.

FIG. 3 is an enlarged view illustrating an area P of FIG. 1.

FIGS. 4 to 10 are views illustrating a semiconductor package according to some other embodiments of the present disclosure.

FIG. 11 is a view illustrating a semiconductor package according to some other embodiments of the present disclosure.

FIG. 12 is an enlarged view of an area Q of FIG. 11.

FIG. 13 is an example plan view illustrating a semiconductor package according to some other embodiments of the present disclosure.

FIGS. 14 and 15 are example cross-sectional views taken along line B-B of FIG. 13.

FIGS. 16 to 25 are views illustrating a process of manufacturing a semiconductor package having a cross-section of FIG. 3.

### DETAILED DESCRIPTION OF THE DISCLOSURE

Hereinafter, embodiments of the inventive concept are described in detail with reference to the accompanying drawings. Identical reference numerals are used for the same constituent elements in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. It will be understood that, although the terms “first”, “second”, “upper portion”, “lower portion”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

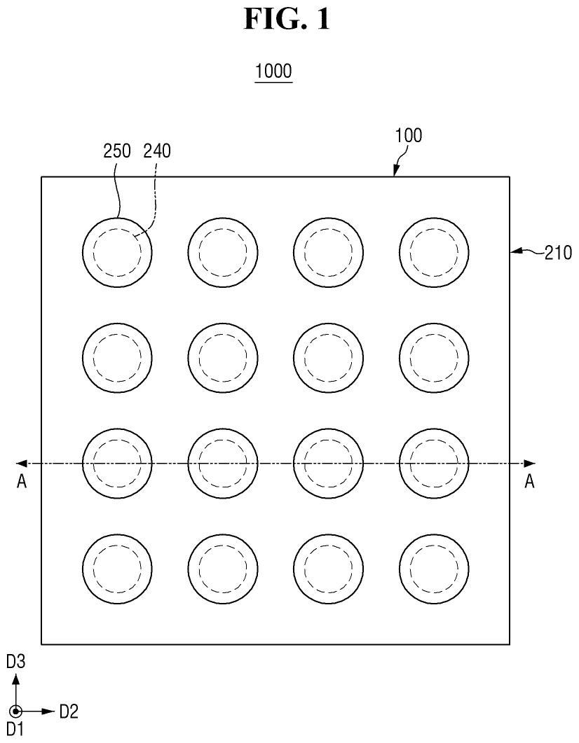

Hereinafter, a semiconductor package according to example embodiments will be described with reference to FIGS. 1 to 15.

First, the semiconductor package according to some embodiments of the present disclosure will be described with reference to FIGS. 1 to 3.

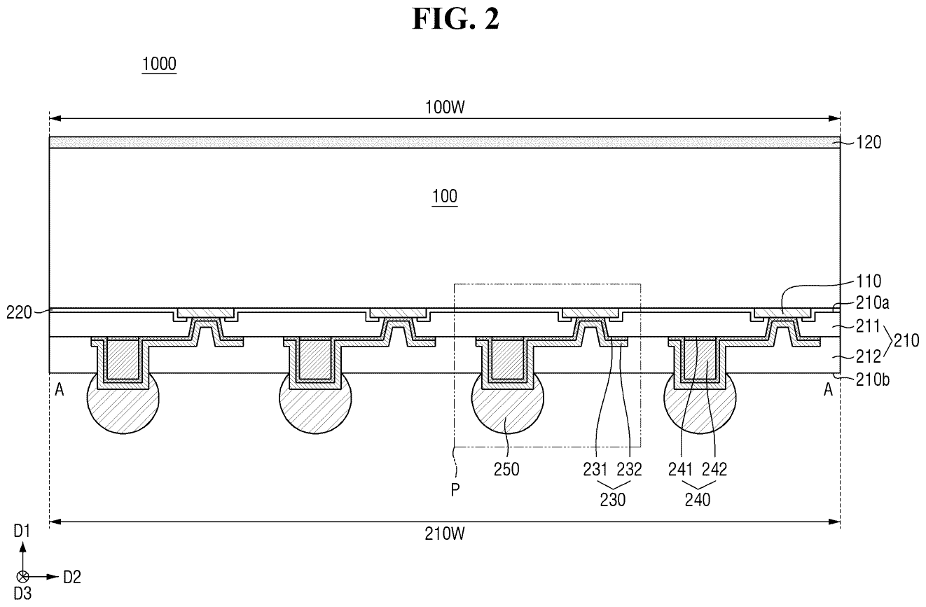

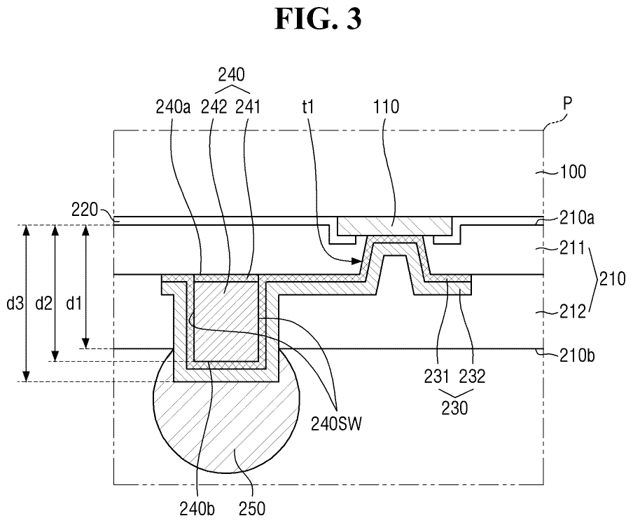

FIG. 1 is an example plan view illustrating a semiconductor package according to some embodiments of the present disclosure. FIG. 2 is an example cross-sectional view taken along line A-A of FIG. 1. FIG. 3 is an enlarged view illustrating an area P of FIG. 1.

Referring to FIGS. 1 to 3, a semiconductor package 1000 according to some embodiments may include a semiconductor chip 100, a redistribution substrate 210, a redistribution pattern 230, a metal pattern 240 and a connection terminal 250.

In some embodiments, a plurality of connection terminals 250 may be spaced apart from each other in a plane formed by the second and third directions D2 and D3, respectively, e.g., a plane in which the second direction D2 and the third direction D3 are extended. For example, the plurality of connection terminals 250 may be spaced apart from each other in the second direction D2 and spaced apart from each other in the third direction D3. The first direction D1, the second direction D2 and the third direction D3 may be substantially perpendicular to one another.

First, the redistribution substrate 210 may be provided. The redistribution substrate 210 may be disposed below in the D1 direction the semiconductor chip 100, which will be described below. The redistribution substrate 210 may include a first surface 210a and a second surface 210b, which are opposite to each other in the first direction D1. The first surface 210a may face the semiconductor chip 100. The second surface 210b may be opposite to the semiconductor chip 100. That is, the semiconductor chip 100 may be packaged on the first surface 210a. The plurality of connection terminals 250, which will be described below, may be disposed on the second surface 210b.

The redistribution substrate 210 may include a first insulating layer 211 and a second insulating layer 212. The first insulating layer 211 and the second insulating layer 212 may be stacked in the first direction D1. The second insulating layer 212 may be disposed on the first insulating layer 211 based on the semiconductor chip 100. The first insulating layer 211 may be disposed on the second insulating layer 212 based on the connection terminal 250.

Each of the first insulating layer 211 and the second insulating layer 212 may comprise a photoimageable dielectric (PID) material. For example, each of the first insulating layer 211 and the second insulating layer 212 may include a photosensitive polymer. The photosensitive polymer may comprise one or more materials including, for example, photosensitive polyimide, polybenzoxazole, a phenolic polymer, and/or a benzocyclobutene-based polymer. For another example, each of the first insulating layer 211 and the second insulating layer 212 may comprise a silicon oxide layer, a silicon nitride layer and/or a silicon oxynitride layer.

In FIG. 2, the redistribution substrate 210 is shown as being formed of two insulating layers, but embodiments of the present disclosure are not limited thereto. The redistribution substrate 210 may comprise three or more insulating layers.

The semiconductor chip 100 may be packaged on the first surface 210a of the redistribution substrate 210. The semiconductor chip 100 may be an integrated circuit (IC) in which several hundreds to millions of semiconductor devices are integrated in one chip.

For example, the semiconductor chip 100 may be a logic semiconductor chip. For example, the semiconductor chip 100 may be an application processor (AP) such as a Central Processing Unit (CPU), a Graphic Processing Unit (GPU), a Field Programmable Gate Array (FPGA), a digital signal processor, an encryption processor, a microprocessor, a microcontroller, and/or an Application-Specific IC (ASIC), but embodiments are not limited thereto.

For another example, the semiconductor chip 100 may be a memory semiconductor chip. For example, the semiconductor chip 100 may be a volatile memory, such as a dynamic random access memory (DRAM) or a static random access memory (SRAM), or may be a non-volatile memory such as a flash memory, a phase-change random access memory (PRAM), a magnetoresistive random access memory (MRAM), a ferroelectric random access memory (FeRAM), or a Resistive Random Access Memory (RRAM).

A chip pad 110 may be disposed below the semiconductor chip 100 in the D1 direction. The chip pad 110 may be provided on a lower surface of the semiconductor chip 100. The lower surface of the semiconductor chip 100 may face the first surface 210a. The semiconductor chip 100 and the redistribution pattern 230 may be electrically connected to each other through the chip pad 110. In addition, the semiconductor chip 100 and the connection terminal 250 may be electrically connected to each other through the chip pad 110.

In some embodiments, a passivation layer 220 may be interposed between the semiconductor chip 100 and the first insulating layer 211. The passivation layer 220 may completely cover the lower surface of the semiconductor chip 100 and expose a portion of the chip pad 110, i.e., the chip pad 110 may be free of the passivation layer 220.

At least a portion of the passivation layer 220 may at least partially surround a lower surface of the chip pad 110 in a plan view from the D1 direction. However, the passivation layer 220 does not completely cover the lower surface of the chip pad 110 and is not on the upper surface of the chip pad 110. The passivation layer 220 may include silicon oxide and/or silicon nitride. The passivation layer 220 may serve to support the semiconductor chip 100 and provide insulating properties between the chip pads 110 spaced apart from each other.

In some embodiments, the metal pattern 240 may be disposed on the first insulating layer 211 based on the semiconductor chip 100. At least a portion of the metal pattern 240 may be disposed in the second insulating layer 212. The metal pattern 240 may pass through the second insulating layer 212 in the first direction D1.

In some embodiments, the metal pattern 240 may include a third surface 240a and a fourth surface 240b, which are opposite to each other in the first direction D1. The third surface 240a of the metal pattern 240 may face the semiconductor chip 100. The fourth surface 240b of the metal pattern 240 may be opposite to the semiconductor chip 100. The metal pattern 240 may be disposed on an upper surface of the first insulating layer 211. In FIG. 3, the upper surface of the first insulating layer 211 may be a surface opposite to the semiconductor chip 100.

In some embodiments, the metal pattern 240 may be in contact with a portion of the first insulating layer 211. For example, the third surface 240a of the metal pattern 240 may be in contact with the upper surface of the first insulating layer 211. This is because that the metal pattern 240 is formed directly on the first insulating layer 211. The metal pattern 240 may not be directly in contact with the second insulating layer 212. The redistribution pattern 230 may be disposed between the metal pattern 240 and the second insulating layer 212.

In some embodiments, the fourth surface 240b of the metal pattern 240 may not completely overlap the second surface 210b of the redistribution substrate 210 in the first direction D1. The metal pattern 240 may completely pass through the second insulating layer 212 in the first direction D1. When the metal pattern 240 is first formed and then the second insulating layer 212 is formed, the second insulating layer 212 may not cover the metal pattern 240, i.e., the metal pattern may be free of the second insulating layer 212.

In some embodiments, the metal pattern 240 may protrude from the second surface 210b in the first direction D1. That is, the second insulating layer 212 does not cover the fourth surface 240b of the metal pattern 240, i.e., the fourth surface 240b may be free of the second insulating layer 212. For example, a first distance d1 in the first direction D1 from the first surface 210a to the second surface 210b is less than a second distance d2 in the first direction D1 from the first surface 210a to the fourth surface 240b. Also, a third distance d3 in the first direction D1 from the first surface 210a to a surface in which the connection terminal 250 is in contact with the redistribution pattern 230 is greater than the first distance d1, but embodiments of the present disclosure are not limited thereto.

In some embodiments, the redistribution substrate 210 may at least partially surround a portion of sidewalls 240SW of the metal pattern 240 in a plan view taken from the D1 direction. For example, the second insulating layer 212 may at least partially surround a portion of the sidewalls 240SW of the metal pattern 240 in a plan view taken from the D1 direction.

In some embodiments, the metal pattern 240 may include a pattern seed layer 241 and a pattern filling layer 242. The pattern seed layer 241 may be formed along the upper surface of the first insulating layer 211. The pattern seed layer 241 may include a conductive metal material. For example, the pattern seed layer 241 may include, but is not limited to, one or more of copper (Cu), aluminum (Al), silver (Ag), tin (Sn), gold (Au), nickel (Ni), lead (Pb), titanium (Ti) or their alloy.

The pattern filling layer 242 may be disposed on the pattern seed layer 241 based on the semiconductor chip 100. The pattern filling layer 242 may be formed using the pattern seed layer 241 as a seed layer. The pattern filling layer 242 may include a conductive metal material. For example, the pattern filling layer 242 may include, but is not limited to, one or more of copper (Cu), aluminum (Al), silver (Ag), tin (Sn), gold (Au), nickel (Ni), lead (Pb), titanium (Ti) or their alloy.

In some embodiments, the metal pattern 240 is not disposed on an upper surface of the second insulating layer 212. In FIG. 3, the upper surface of the second insulating layer 212 may be a surface opposite to the semiconductor chip 100. The upper surface of the second insulating layer 212 may face the connection terminal 250. The upper surface of the second insulating layer 212 may be the second surface 210b of the redistribution substrate 210. The metal pattern 240 is not in contact with the upper surface of the second insulating layer 212. The metal pattern 240 is not in contact with the second surface 210b of the redistribution substrate 210.

Therefore, damage caused by a difference in coefficient of thermal expansion (CTE) between the metal pattern 240 and the second insulating layer 212 may be reduced. Therefore, the semiconductor package 1000 with improved reliability may be manufactured.

A plurality of connection terminals 250 may be provided on the metal pattern 240 based on the semiconductor chip 100. The plurality of connection terminals 250 may be electrically connected to the metal pattern 240. The plurality of connection terminals 250 may be in contact with a portion of the redistribution pattern 230. A portion of the redistribution pattern 230 may be interposed between each of the connection terminals 250 and the metal pattern 240. That is, each of the connection terminals 250 and the metal pattern 240 may be electrically connected to each other through the redistribution pattern 230.

Each of the plurality of connection terminals 250 is shown as having a ball shape, but embodiments of the present disclosure are not limited thereto. Each of the plurality of connection terminals 250 may have various shapes such as a land, a ball, a pin and a pillar. The number, interval, arrangement form and the like of the plurality of connection terminals 250 are not limited to the shown examples, and may vary depending on design. Each of the plurality of connection terminals 250 may be a solder bump that includes a low melting point metal, for example, tin (Sn) and a tin (Sn) alloy, but embodiments are not limited thereto.

In some embodiments, the redistribution pattern 230 may be disposed in the redistribution substrate 210. The redistribution pattern 230 may be electrically connected to the chip pad 110. The redistribution pattern 230 may be electrically connected to the metal pattern 240.

In some embodiments, the first insulating layer 211 may include a first trench t1 that exposes the chip pad 110. A width of the first trench t1 may be gradually reduced from the upper surface of the first insulating layer 211 toward the semiconductor chip 100.

The redistribution pattern 230 may be in and may fill at least a portion of the first trench t1. For example, the redistribution pattern 230 may extend along a bottom surface and sidewalls of the first trench t1. In addition, the redistribution pattern 230 may extend along the upper surface of the first insulating layer 211. In this way, at least a portion of the redistribution pattern 230 may extend from the upper surface of the first insulating layer 211 toward the bottom surface of the first trench t1.

In some embodiments, the redistribution pattern 230 may be in contact with the sidewalls 240SW of the metal pattern 240. The redistribution pattern 230 may be in contact with the fourth surface 240b of the metal pattern 240. For example, the redistribution pattern 230 may be on and may completely surround the sidewalls 240SW and the fourth surface 240b of the metal pattern 240 as shown in FIG. 3. The redistribution pattern 230 is not in contact with the third surface 240a of the metal pattern 240. This is because that the redistribution pattern 230 is formed after the metal pattern 240 is first formed on the first insulating layer 211.

In some embodiments, the redistribution pattern 230 may include a redistribution seed layer 231 and a redistribution filling layer 232. The redistribution seed layer 231 may extend along the sidewalls and the bottom surface of the first trench t1, the upper surface of the first insulating layer 211, the sidewalls 240SW of the metal pattern 240 and the fourth surface 240b of the metal pattern 240. The redistribution seed layer 231 may be on and may completely surround the sidewalls 240SW and the fourth surface 240b of the metal pattern 240 as shown in FIG. 3. The redistribution filling layer 232 may be disposed on the redistribution seed layer 231. The redistribution filling layer 232 may be formed using the redistribution seed layer 231 as a seed layer.

In some embodiments, at least a portion of the redistribution pattern 230 may be interposed between the metal pattern 240 and the connection terminal 250. That is, the connection terminal 250 may be directly in contact with the redistribution pattern 230 but may not be directly in contact with the metal pattern 240. Also, the redistribution pattern 230 may not be disposed between the first insulating layer 211 and the third surface 240a of the metal pattern 240.

In some embodiments, a portion of the second insulating layer 212 may be disposed in the first trench t1. A portion of the second insulating layer 212 may or may not be disposed in the first trench t1 depending on a depth of the first trench t1, the width of the first trench t1 and a thickness of the redistribution pattern 230. FIG. 3 shows that a portion of the second insulating layer 212 is disposed in the first trench t1, but embodiments of the present disclosure are not limited thereto. The second insulating layer 212 may not be disposed in the first trench t1.

The redistribution seed layer 231 may include a conductive metal material. For example, the redistribution seed layer 231 may include, but is not limited to, one or more materials, such as copper (Cu), aluminum (Al), silver (Ag), tin (Sn), gold (Au), nickel (Ni), lead (Pb), titanium (Ti) or their alloy.

The redistribution filling layer 232 may include a conductive metal material. For example, the redistribution filling layer 232 may include, but is not limited to, one or more materials, such as copper (Cu), aluminum (Al), silver (Ag), tin (Sn), gold (Au), nickel (Ni), lead (Pb), titanium (Ti) or their alloy.

In some embodiments, a passivation film 120 may be disposed on an upper surface of the semiconductor chip 100. The passivation film 120 may be on and may completely cover the upper surface of the semiconductor chip 100. The passivation film 120 may protect the semiconductor chip 100.

In some embodiments, a width 100W of the semiconductor chip 100 may be the same as a width 210W of the redistribution substrate 210. For example, in FIG. 2, the width 100W of the semiconductor chip 100 in the second direction D2 may be the same as the width 210W of the redistribution substrate 210 in the second direction D2. In FIG. 1, a width of the semiconductor chip 100 in the third direction D3 may be the same as a width of the redistribution substrate 210 in the third direction D3. In addition, the width of the semiconductor chip 100 may be the same as a width of the first insulating layer 211 and a width of the second insulating layer 212. Sidewalls of the semiconductor chip 100 may be aligned with those of the redistribution substrate 210.

That is, the semiconductor package 1000 according to some embodiments of the present disclosure may be a fan-in wafer level package (FIWLP), but embodiments of the present disclosure are not limited thereto.

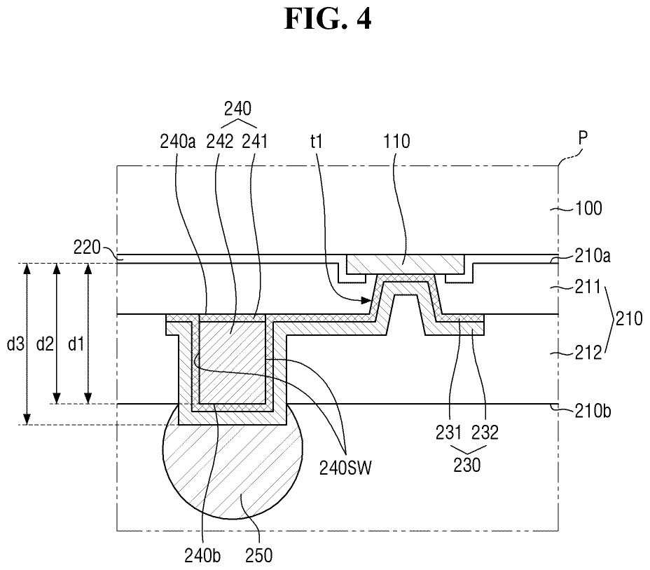

Hereinafter, the semiconductor package according to some other embodiments of the present disclosure will be described with reference to FIGS. 4 to 10. FIGS. 4 to 10 are views illustrating a semiconductor package according to some other embodiments of the present disclosure. For convenience of description, redundant descriptions with those described with reference to FIGS. 1 to 3 will be briefly described or omitted.

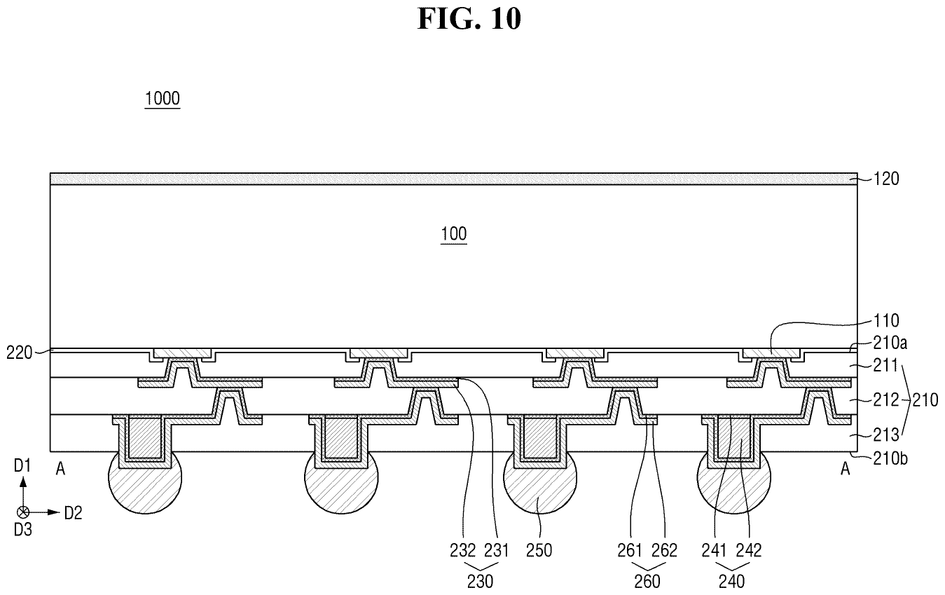

For reference, FIGS. 4 to 9 are views illustrating various embodiments of the metal pattern 240 and the redistribution patterns 230 of the present disclosure. For reference, FIG. 10 may be an example cross-sectional view taken along line A-A of FIG. 1.

First, referring to FIG. 4, the first distance d1 in the first direction D1 from the first surface 210a to the second surface 210b is the same as the second distance d2 in the first direction D1 from the first surface 210a to the third surface 240b. That is, the second surface 210b and the fourth surface 240b are coplanar.

A portion of the redistribution pattern 230 may protrude from the second surface 210b. That is, the third distance d3 in the first direction D1 from the first surface 210a to the surface in which the connection terminal 250 is in contact with the redistribution pattern 230 is greater than the first distance d1. In addition, even in FIG. 4, the second surface 210b and the fourth surface 240b do not overlap each other in the first direction D1.

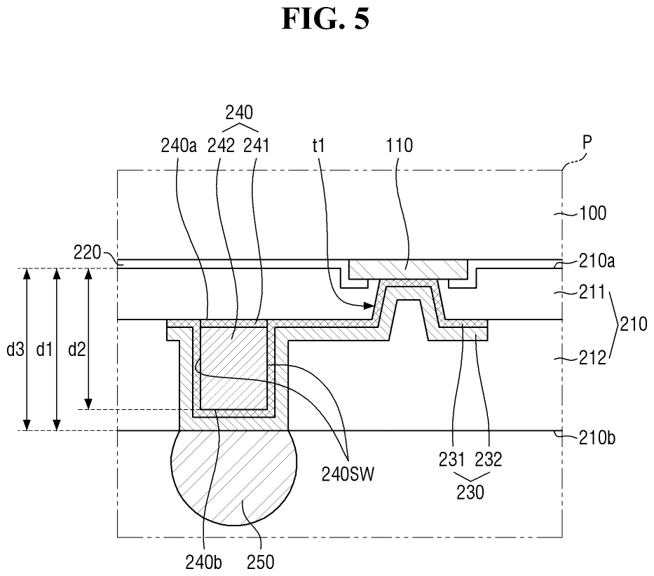

Referring to FIG. 5, the first distance d1 in the first direction D1 from the first surface 210a to the second surface 210b is greater than the second distance d2 from the first surface 210a to the third surface 240b in the first direction D1. In this case, the third distance d3 in the first direction D1 from the first surface 210a to the surface in which the connection terminal 250 is in contact with the redistribution pattern 230 may be the same as the first distance d1. In addition, even in FIG. 5, the second surface 210b and the fourth surface 240b do not overlap each other in the first direction D1.

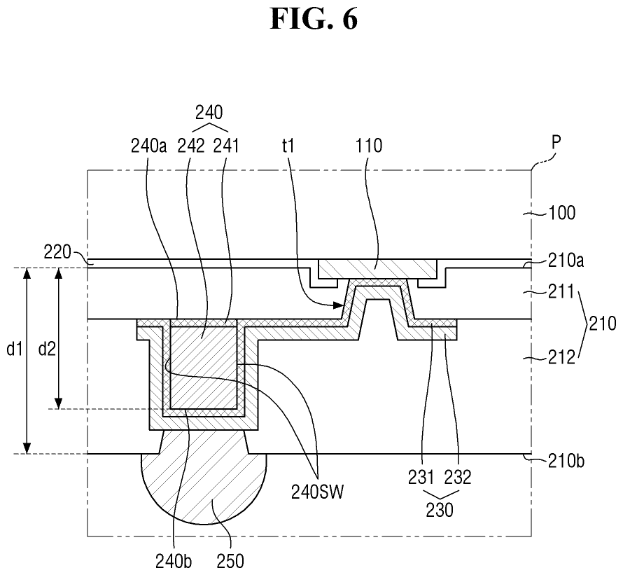

Referring to FIG. 6, at least a portion of the second insulating layer 212 may be disposed on the fourth surface 240b of the metal pattern 240. At least a portion of the second insulating layer 212 may be on and at least partially cover a portion of the redistribution pattern 230 disposed on the fourth surface 240b of the metal pattern 240. The metal pattern 240 does not completely pass through the second insulating layer 212. The second insulating layer 212 may expose at least a portion of the redistribution pattern 230. The exposed redistribution pattern 230 may be electrically connected to the connection terminal 250. Therefore, the metal pattern 240 and the connection terminal 250 may be electrically connected to each other. At least a portion of the second surface 210b may overlap the fourth surface 240b in the first direction D1, and the second surface 210b may not completely overlap the fourth surface 240b in the first direction D1.

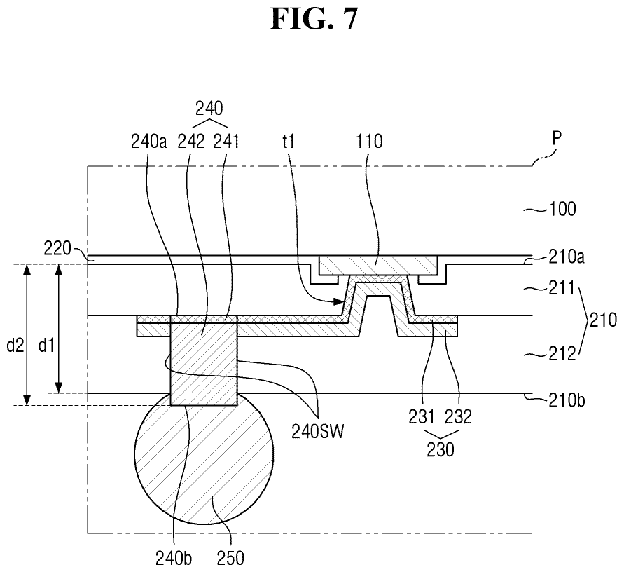

Referring to FIG. 7, the redistribution pattern 230 does not extend along the sidewalls 240SW and the fourth surface 240b of the metal pattern 240. The redistribution pattern 230 may be on and at least partially cover a portion of the sidewalls 240SW of the metal pattern 240. The redistribution pattern 230 may not cover another portion of the sidewalls 240SW of the metal pattern 240, i.e., a portion of the sidewalls 240SW of the metal pattern 240 may be free of the redistribution pattern 230.

The redistribution seed layer 231 extends along the upper surface of the first insulating layer 211 and a profile of the first trench t1, and does not extend along the sidewalls 240SW of the metal pattern 240. Further, the redistribution seed layer 231 does not extend along the fourth surface 240b of the metal pattern 240. Therefore, the redistribution filling layer 232 does not extend along the sidewalls 240SW of the metal pattern 240 and the fourth surface 240b of the metal pattern 240. The redistribution filling layer 232 may be formed using the redistribution seed layer 231 as a seed layer.

In some embodiments, the redistribution pattern 230 is not interposed between the metal pattern 240 and the connection terminal 250. That is, the connection terminal 250 is not directly in contact with the redistribution pattern 230. The connection terminal 250 may be directly in contact with the metal pattern 240. At this time, the redistribution pattern 230 is not disposed between the first insulating layer 211 and the third surface 240a of the metal pattern 240. Because the redistribution pattern 230 does not completely cover the sidewalls 240SW of the metal pattern 240, a portion of the sidewalls 240SW of the metal pattern 240 may be in contact with the second insulation layer 212.

In some embodiments, at least a portion of the metal pattern 240 may protrude from the second surface 210b. Thus, at least a portion of the sidewalls 240SW of the metal pattern 240 may be exposed. The exposed sidewalls 240SW of the metal pattern 240 may be in contact with the connection terminal 250, but embodiments of the present disclosure are not limited thereto.

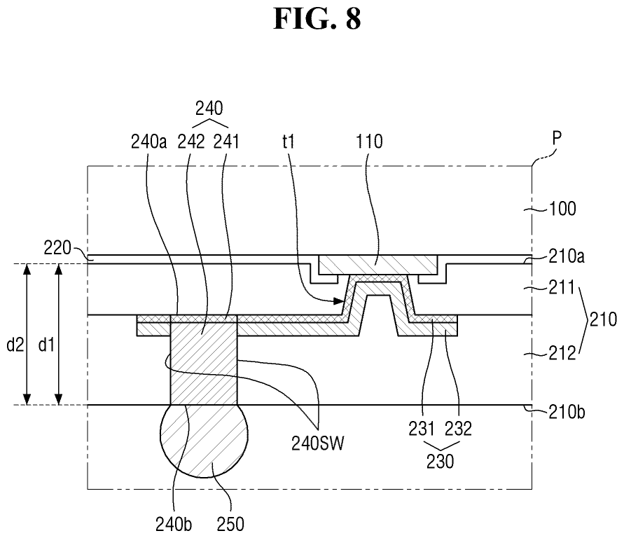

Referring to FIG. 8, the fourth surface 240b of the metal pattern 240 may be coplanar with the second surface 210b of the redistribution substrate 210. That is, the sidewalls 240SW of the metal pattern 240 not covered by the redistribution pattern 230 may be completely covered by the second insulation layer 212. Therefore, the connection terminal 250 is not in contact with the sidewalls 240SW of the metal pattern 240. The connection terminal 250 may be directly in contact with the fourth surface 240b of the metal pattern 240.

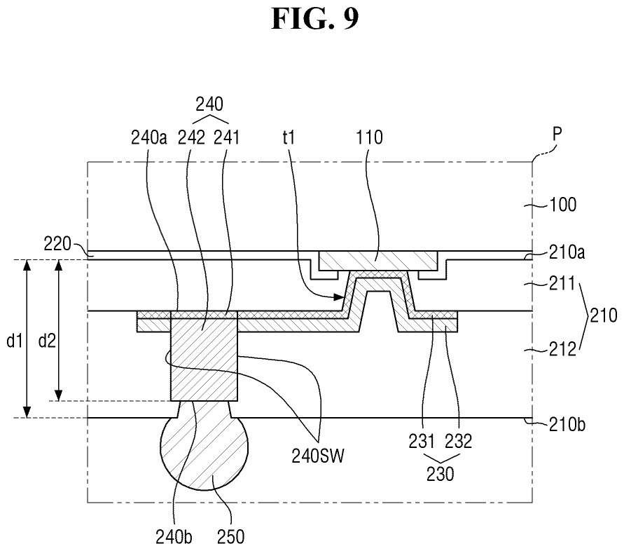

Referring to FIG. 9, at least a portion of the second insulating layer 212 may be disposed on the fourth surface 240b of the metal pattern 240. The metal pattern 240 does not completely pass through the second insulating layer 212. The second insulating layer 212 may expose at least a portion of the fourth surface 240b of the metal pattern 240, i.e., at least a portion of the fourth surface 240b of the metal pattern 240 may be free of the second insulating layer 212. The exposed fourth surface 240b of the metal pattern 240 may be electrically connected to the connection terminal 250. In this case, at least a portion of the second surface 210b may overlap the fourth surface 240b in the first direction D1.

Referring to FIG. 10, the semiconductor package 1000 according to some embodiments may further include a third insulating layer 213.

For example, the redistribution substrate 210 may include a first insulating layer 211, a second insulating layer 212 and a third insulating layer 213. The first insulating layer 211 is disposed on the semiconductor chip 100 based on the semiconductor chip 100. The second insulating layer 212 is disposed on the first insulating layer 211. The third insulating layer 213 is disposed on the second insulating layer 212. The second insulating layer 212 is disposed between the first insulating layer 211 and the third insulating layer 213.

Each of the first to third insulating layers 211, 212 and 213 may be formed of a photoimageable dielectric (PID) material. For example, each of the first to third insulating layers 211, 212 and 213 may include a photosensitive polymer. The photosensitive polymer may comprise one or more materials, such as, for example, a photosensitive polyimide, polybenzoxazole, a phenolic polymer or a benzocyclobutene-based polymer. For another example, each of the first to third insulating layers 211, 212 and 213 may be formed of a silicon oxide layer, a silicon nitride layer and/or a silicon oxynitride layer.

The first redistribution pattern 230 and the second redistribution pattern 260 may be disposed in the redistribution substrate 210. One end of the first redistribution pattern 230 may be electrically connected to the chip pad 110. The other end of the first redistribution pattern 230 may be electrically connected to the second redistribution pattern 260. One end of the second redistribution pattern 260 may be electrically connected to the first redistribution pattern 230. The other end of the second redistribution pattern 260 may be electrically connected to the metal pattern 240 and the connection terminal 250. The metal pattern 240 and the connection terminal 250 may be electrically connected to the second redistribution pattern 260, respectively.

In some embodiments, the first redistribution pattern 230 includes a first redistribution seed layer 231 and a first redistribution filling layer 232. The first redistribution filling layer 232 may be formed using the first redistribution seed layer 231 as a seed layer.

In some embodiments, the second redistribution pattern 260 includes a second redistribution seed layer 261 and a second redistribution filling layer 262. The second redistribution filling layer 262 may be formed using the second redistribution seed layer 261 as a seed layer.

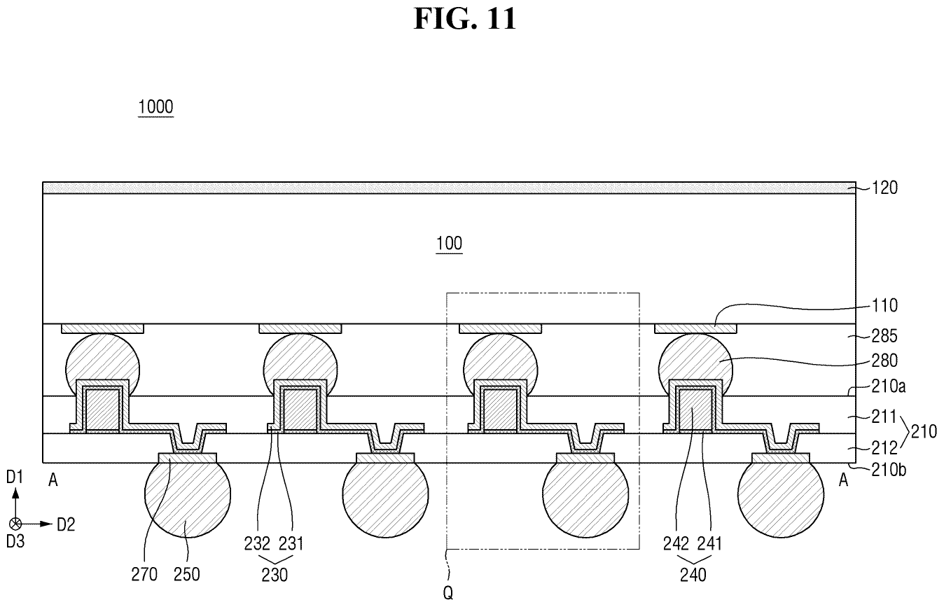

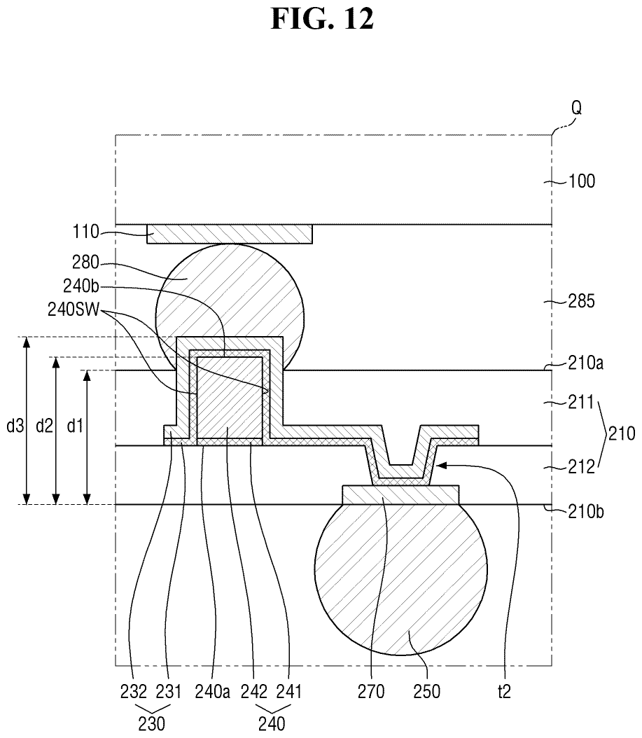

Hereinafter, the semiconductor package according to some other embodiments of the present disclosure will be described below with reference to FIGS. 11 and 12. For convenience of description, redundant descriptions with those described with reference to FIGS. 1 to 3 will be briefly described or omitted.

FIG. 11 is a view illustrating a semiconductor package according to some other embodiments of the present disclosure. FIG. 12 is an enlarged view of an area Q of FIG. 11.

Referring to FIGS. 11 and 12, the semiconductor package 1000 according to some embodiments may include a semiconductor chip 100, a redistribution substrate 210, an underfill 285, a first connection terminal 250, a second connection terminal 280, a ball pad 270, a metal pattern 240, and a redistribution pattern 230.

The redistribution substrate 210 may include a first insulating layer 211 and a second insulating layer 212. The first insulating layer 211 and the second insulating layer 212 may be stacked in the first direction D1. The first insulating layer 211 may be disposed on the second insulating layer 212 based on the first connection terminal 250.

The ball pad 270 may be disposed in the second insulating layer 212. The ball pad 270 may expose a lower surface of the second insulating layer 212, i.e., a portion of the ball pad 270 may be free of the second insulating layer 212. In FIGS. 11 and 12, the lower surface of the second insulating layer 212 may be the second surface 210b of the redistribution substrate 210. The ball pad 270 may be electrically connected to the first connection terminal 250. The ball pad 270 may be interposed between the first connection terminal 250 and the redistribution pattern 230 to electrically connect the first connection terminal 250 with the redistribution pattern 230.

The ball pad 270 may include a conductive metal material. For example, the ball pad 270 may include, but is not limited to, one or more materials, such as, copper (Cu), aluminum (Al), silver (Ag), tin (Sn), gold (Au), nickel (Ni), lead (Pb), titanium (Ti) or their alloy.

In some embodiments, the metal pattern 240 may be disposed on the second insulating layer 212 based on the first connection terminal 250. At least a portion of the metal pattern 240 may be disposed in the first insulating layer 211. The metal pattern 240 may pass through the first insulating layer 211 in the first direction D1.

In some embodiments, the metal pattern 240 may include a third surface 240a and a fourth surface 240b, which are opposite to each other in the first direction D1. In FIG. 12, the fourth surface 240b of the metal pattern 240 may face the semiconductor chip 100. The third surface 240a of the metal pattern 240 may be opposite to the semiconductor chip 100. The metal pattern 240 may be disposed on the upper surface of the second insulating layer 212.

In some embodiments, the metal pattern 240 may be in contact with a portion of the second insulating layer 212. For example, the third surface 240a of the metal pattern 240 may be in contact with the upper surface of the second insulating layer 212. This is because that the metal pattern 240 is formed directly on the second insulating layer 212. The metal pattern 240 may not be in contact with the first insulating layer 211. The redistribution pattern 230 may be disposed between the metal pattern 240 and the first insulating layer 211, but embodiments of the present disclosure are not limited thereto.

The redistribution pattern 230 may be on and may cover only a portion of the sidewalls of the metal pattern 240. The redistribution pattern 230 may not cover the fourth surface 240b of the metal pattern 240, i.e., the fourth surface 240b of the metal pattern 240 may be free of the redistribution pattern.

In some embodiments, the fourth surface 240b of the metal pattern 240 may not completely overlap the second surface 210b of the redistribution substrate 210 in the first direction D1. The metal pattern 240 may completely pass through the first insulating layer 211 in the first direction D1.

In some embodiments, the metal pattern 240 may protrude from the first surface 210a in the first direction D1. That is, the first insulating layer 211 does not cover the fourth surface 240b of the metal pattern 240, i.e., the fourth surface 240b is free of the first insulating layer 211. For example, the first distance d1 in the first direction D1 from the second surface 210b to the first surface 210a is less than the second distance d2 in the first direction D1 from the second surface 210b to the fourth surface 240b. Also, the third distance d3 in the first direction D1 from the second surface 210b to the surface in which the second connection terminal 280 is in contact with the redistribution pattern 230 is greater than the first distance d1, but embodiments of the present disclosure are not limited thereto.

In some embodiments, the redistribution substrate 210 may at least partially surround a portion of the sidewalls 240SW of the metal pattern 240 in a plan view taken from the D1 direction. For example, the first insulating layer 211 may surround a portion of the sidewalls 240SW of the metal pattern 240.

In some embodiments, the metal pattern 240 may include a pattern seed layer 241 and a pattern filling layer 242. The pattern seed layer 241 may be formed along the upper surface of the second insulating layer 212. The pattern filling layer 242 may be disposed on the pattern seed layer 241 based on the first connection terminal 250. The pattern filling layer 242 may be formed using the pattern seed layer 241 as a seed layer.

In some embodiments, the metal pattern 240 is not disposed on the upper surface of the first insulating layer 211. In FIG. 12, the upper surface of the first insulating layer 211 may be a surface facing the semiconductor chip 100. The upper surface of the first insulating layer 211 may be the first surface 210a of the redistribution substrate 210. The metal pattern 240 is not in contact with the upper surface of the first insulating layer 211. The metal pattern 240 is not in contact with the first surface 210a of the redistribution substrate 210. Therefore, damage caused by a difference in coefficient of thermal expansion (CTE) between the metal pattern 240 and the first insulating layer 211 may be reduced. Therefore, the semiconductor package 1000 with improved reliability may be manufactured.

A plurality of connection terminals 250 may be provided on the ball pad 270 based on the semiconductor chip 100.

A plurality of second connection terminals 280 may be provided on the metal pattern 240 based on the first connection terminal 250. The plurality of second connection terminals 280 may be provided on the fourth surface 240b of the metal pattern 240. The plurality of second connection terminals 280 may be interposed between the metal pattern 240 and the chip pad 110. The plurality of second connection terminals 280 may be in contact with a portion of the redistribution pattern 230. A portion of the redistribution pattern 230 may be interposed between each of the second connection terminals 280 and the metal pattern 240. That is, each of the second connection terminals 280 and the metal pattern 240 may be electrically connected to each other through the redistribution pattern 230.

Each of the plurality of second connection terminals 280 is shown as having a ball shape, but embodiments of the present disclosure are not limited thereto. Each of the plurality of second connection terminals 280 may have various shapes, such as a land, a ball, a pin, and a pillar in accordance with different embodiments. The number, interval, arrangement form and the like of the plurality of second connection terminals 280 are not limited to the shown examples, and may vary depending on design. Each of the plurality of second connection terminals 280 may be a solder bump that includes a low melting point metal, for example, tin (Sn) and a tin (Sn) alloy, but embodiments are not limited thereto.

The underfill 285 may be formed between the redistribution substrate 210 and the semiconductor chip 100. The underfill 285 may at least partially fill a space between the redistribution substrate 210 and the semiconductor chip 100. The underfill 285 may also be on and at least partially cover the second connection terminal 280. The underfill 285 may include, for example, an insulating polymer material, such as an epoxy molding compound (EMC), but embodiments are not limited thereto.

In some embodiments, the redistribution pattern 230 may be disposed in the redistribution substrate 210. One end of the redistribution pattern 230 may be electrically connected to the metal pattern 240. The other end of the redistribution pattern 230 may be electrically connected to the ball pad 270.

In some embodiments, the second insulating layer 212 may include a second trench t2 that exposes the ball pad 270. The redistribution pattern 230 may fill at least a portion of the second trench t2. For example, the redistribution pattern 230 may extend along a bottom surface and sidewalls of the second trench t2. In addition, the redistribution pattern 230 may extend along the upper surface of the second insulating layer 212. In this way, at least a portion of the redistribution pattern 230 may extend from the upper surface of the second insulating layer 212 toward the bottom surface of the second trench t2. The upper surface of the second insulating layer 212 may face the semiconductor chip 100.

In some embodiments, the redistribution pattern 230 may be in contact with the sidewalls 240SW of the metal pattern 240. The redistribution pattern 230 may be in contact with the fourth surface 240b of the metal pattern 240. For example, the redistribution pattern 230 may completely surround the sidewalls 240SW and the fourth surface 240b of the metal pattern 240 as shown in FIG. 12. The redistribution pattern 230 is not in contact with the third surface 240a of the metal pattern 240. This is because the redistribution pattern 230 is formed after the metal pattern 240 is first formed on the second insulating layer 212.

In some embodiments, the redistribution pattern 230 may include a redistribution seed layer 231 and a redistribution filling layer 232. The redistribution seed layer 231 may extend along the sidewalls and the bottom surface of the second trench t2, the upper surface of the second insulating layer 212, the sidewalls 240SW of the metal pattern 240 and the fourth surface 240b of the metal pattern 240. The redistribution seed layer 231 may completely surround the sidewalls 240SW and the fourth surface 240b of the metal pattern 240 as shown in FIG. 12. The redistribution filling layer 232 may be disposed on the redistribution seed layer 231. The redistribution filling layer 232 may be formed using the redistribution seed layer 231 as a seed layer.

In some embodiments, at least a portion of the redistribution pattern 230 may be interposed between the metal pattern 240 and the second connection terminal 280. That is, the second connection terminal 280 may be directly in contact with the redistribution pattern 230 but may not be directly in contact with the metal pattern 240. Also, the redistribution pattern 230 may not be disposed between the second insulating layer 212 and the third surface 240a of the metal pattern 240.

In some embodiments, a portion of the first insulating layer 211 may be disposed in the second trench t2. A portion of the first insulating layer 211 may or may not be disposed in the second trench t2 depending on a depth of the second trench t2, a width of the second trench t2 and a thickness of the redistribution pattern 230. FIG. 12 shows that a portion of the first insulating layer 211 is disposed in the second trench t2, but embodiments of the present disclosure are not limited thereto. The first insulating layer 211 may not be disposed in the second trench t2.

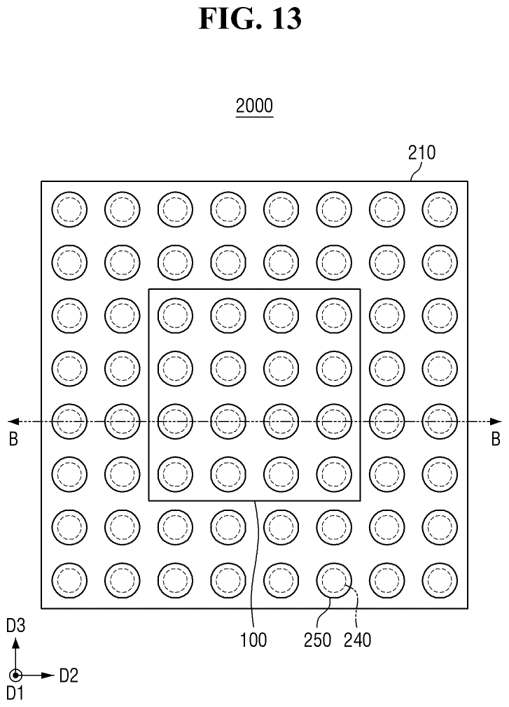

Hereinafter, the semiconductor package according to some other embodiments of the present disclosure will be described below with reference to FIGS. 13 to 15. For convenience of description, redundant descriptions with those described with reference to FIGS. 1 to 3 will be briefly described or omitted.

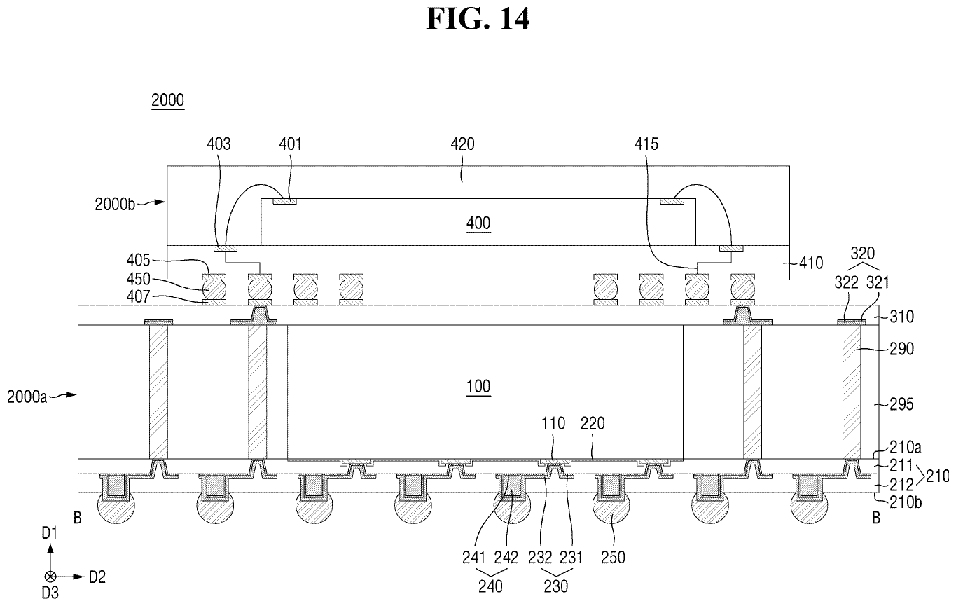

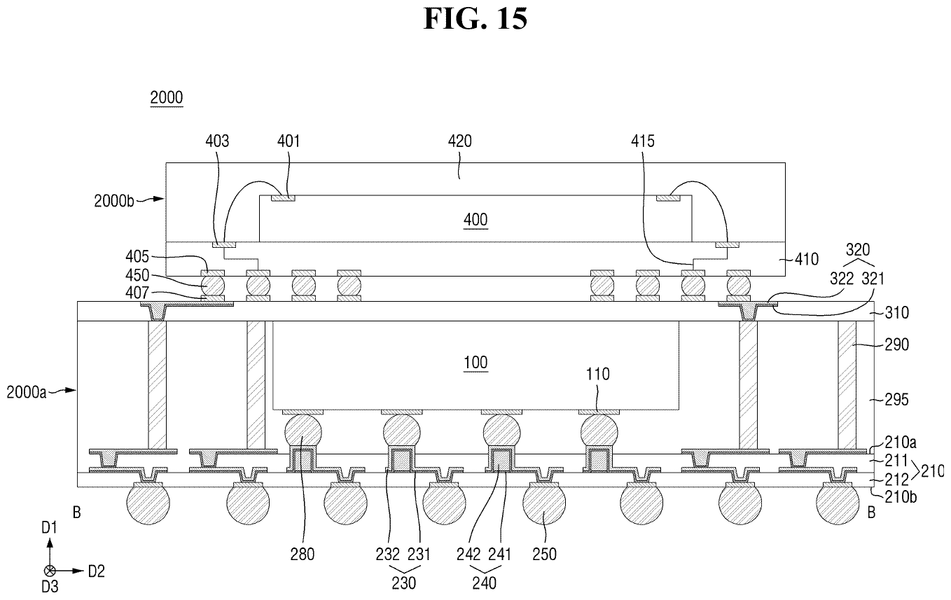

FIG. 13 is an example plan view illustrating a semiconductor package according to some other embodiments of the present disclosure. FIGS. 14 and 15 are example cross-sectional views taken along line B-B of FIG. 13.

First, referring to FIGS. 13 and 14, a semiconductor package 2000 according to some embodiments may be a fan-out wafer level package. That is, a width of the semiconductor chip 100 may be smaller than that of the redistribution substrate 210.

The semiconductor package 2000 according to some embodiments may include a first semiconductor package 2000a and a second semiconductor package 2000b provided on the first semiconductor package 2000a.

The first semiconductor package 2000a may include a redistribution substrate 210, an upper redistribution substrate 310, a semiconductor chip 100, a metal pattern 240, a redistribution pattern 230, a molding layer 295, and a plurality of metal pillars 290. Because the redistribution substrate 210, the semiconductor chip 100, the metal pattern 240 and the redistribution pattern 230 are the same as those described with reference to FIGS. 1 to 3, their detailed description will be omitted.

The plurality of metal pillars 290 may be provided around the semiconductor chip 100. The plurality of metal pillars 290 may electrically connect the redistribution pattern 230 with the upper redistribution pattern 320. The plurality of metal pillars 290 may pass through the molding layer 295. An upper surface of the plurality of metal pillars 290 may be coplanar with an upper surface of the molding layer 295. A lower surface of the plurality of metal pillars 290 may be in contact with the redistribution patterns 230.

The molding layer 295 may be provided between the redistribution substrate 210 and the upper redistribution substrate 310. The molding layer 295 may at least partially fill spaces between the metal pillars 290. A thickness of the molding layer 295 may be substantially the same as that of the metal pillars 290. The molding layer 295 may include an insulating polymer, such as an epoxy molding compound.

The upper redistribution substrate 310 may be formed of an insulating material. For example, the upper redistribution substrate 310 may include the same material as that included in the first and second insulating layers 211 and 212.

For example, the upper redistribution substrate 310 may be made of a photoimageable dielectric material. The upper redistribution substrate 310 may include a photosensitive polymer. The photosensitive polymer may be formed of at least one of, for example, photosensitive polyimide, polybenzoxazole, a phenolic polymer, and/or a benzocyclobutene-based polymer. For another example, the upper retribution substrate 310 may be formed of a silicon oxide layer, a silicon nitride layer, and/or a silicon oxynitride layer.

The upper redistribution pattern 320 may include the same material as that of the redistribution pattern 230. For example, the upper redistribution pattern 320 may include copper (Cu), but embodiments are not limited thereto.

The second semiconductor package 2000b may be disposed on the upper redistribution substrate 310. The second semiconductor package 2000b may include a circuit board 410, an upper semiconductor chip 400 and an upper molding layer 420. The circuit board 410 may be a printed circuit board, but embodiments are not limited thereto. A lower conductive pad 405 may be disposed on a lower surface of the circuit board 410.

The upper semiconductor chip 400 may be disposed on the circuit board 410. The upper semiconductor chip 400 may include integrated circuits. The integrated circuits may include a memory circuit, a logic circuit, or their combination. Upper chip pads 401 of the upper semiconductor chip 400 may be electrically connected to an upper conductive pad 403 of the upper surface of the circuit board 410 by wire bonding. The upper conductive pad 403 of the upper surface of the circuit board 410 may be electrically connected to the lower conductive pad 405 through an internal wiring 415 in the circuit board 410.

The upper molding layer 420 may be provided on the circuit board 410. The upper molding layer 420 may be on and at least partially cover the upper semiconductor chip 400. The upper molding layer 420 may include an insulating polymer, such as an epoxy-based polymer.

The semiconductor package 2000 according to some embodiments may further include a plurality of connection terminals 450. The plurality of connection terminals 450 may be provided between the lower conductive pad 405 and an upper ball pad 407 of the circuit board 410. The plurality of connection terminals 450 may be solder bumps including a low melting point metal, for example, tin (Sn), and/or a tin (Sn) alloy, but embodiments are not limited thereto. The plurality of connection terminals 450 may have various shapes, such as a land, a ball, a pin, and a pillar. The plurality of connection terminals 450 may be formed of a single layer or multiple layers. When the plurality of connection terminals 450 are formed of a single layer, the plurality of connection terminals 450 may include, for example, a tin-silver (Sn—Ag) solder, and/or copper (Cu). When the plurality of connection terminals 450 are formed of multiple layers, the plurality of connection terminals 450 may include, for example, a copper (Cu) pillar and a solder. The number, interval, arrangement, form, and the like of the plurality of connection terminals 450 are not limited to the shown examples, and may vary depending on design.

Referring to FIG. 15, the semiconductor package 2000 according to some embodiments may have a chip last structure. Therefore, the metal pattern 240 of the first semiconductor package 2000a may be connected to the second connection terminal 280 disposed below the semiconductor chip 100.

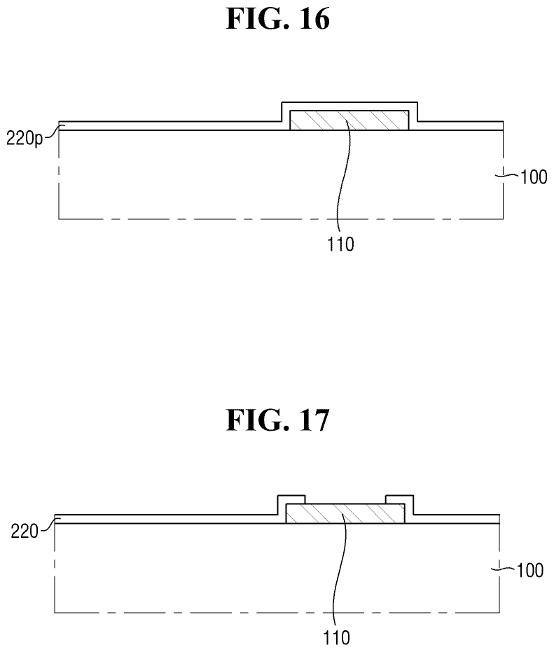

Hereinafter, a method for manufacturing a semiconductor package according to some embodiments of the present disclosure will be described with reference to FIGS. 16 to 25. FIGS. 16 to 25 are views illustrating a process of manufacturing a semiconductor package having a cross-section of FIG. 3. For convenience of description, a process of manufacturing a semiconductor package will be described based on an enlarged view.

First of all, referring to FIG. 16, the semiconductor chip 100 is provided. The chip pad 110 may be formed on the semiconductor chip 100. Subsequently, a pre-passivation layer 220P may be formed. The pre-passivation layer 220P may completely cover the chip pad 110.

Referring to FIG. 17, a portion of the pre-passivation layer 220P may be removed so that the passivation layer 220 may be formed. A portion of the pre-passivation layer 220P may be removed so that a portion of the chip pad 110 may be exposed.

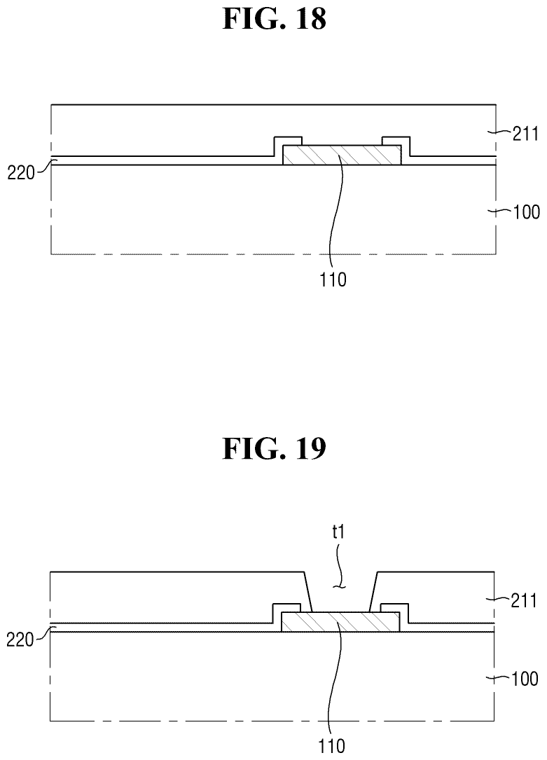

Referring to FIG. 18, the first insulating layer 211 may be formed on the chip pad 110 and the passivation layer 220. The first insulating layer 211 may completely cover the chip pad 110 and the passivation layer 220. The first insulating layer 211 may be formed of a photoimageable dielectric material.

Referring to FIG. 19, a portion of the first insulating layer 211 may be removed so that the first trench t1 may be formed. The first trench t1 may expose at least a portion of the chip pad 110. The first trench t1 does not expose the passivation layer 220.

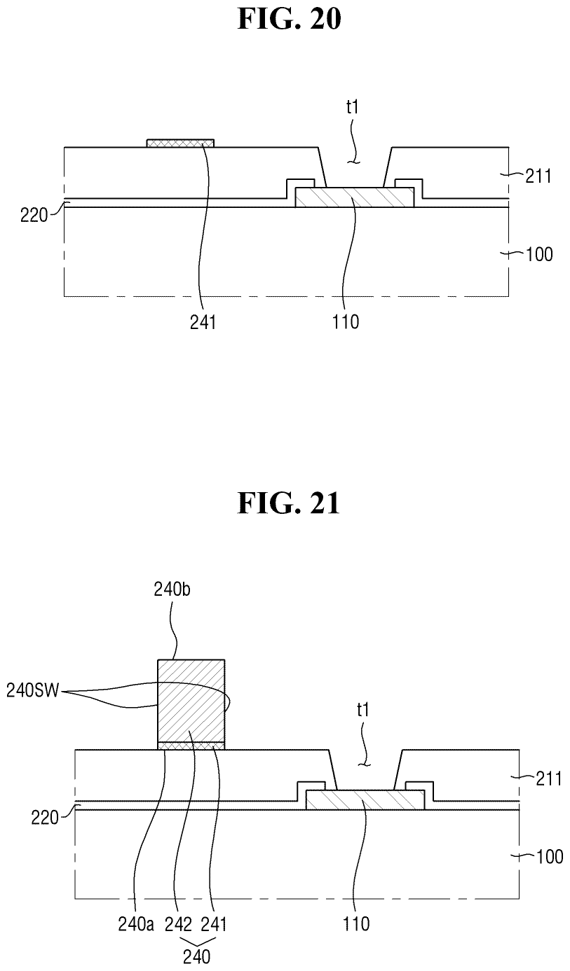

Referring to FIG. 20, the pattern seed layer 241 may be formed on the upper surface of the first insulating layer 211. The upper surface of the first insulating layer 211 may be opposite to the semiconductor chip 100. The pattern seed layer 241 may be formed of, for example, copper (Cu), but embodiments are not limited thereto.

Referring to FIG. 21, the pattern filling layer 242 may be formed. The pattern filling layer 242 may be formed on the pattern seed layer 241. The pattern filling layer 242 may be formed using the pattern seed layer 241 as a seed layer. The pattern filling layer 242 and the pattern seed layer 241 may constitute the metal pattern 240.

The metal pattern 240 includes a third surface 240a and a fourth surface 240b, which are opposite to each other. The metal pattern 240 includes sidewalls 240SW for connecting the third surface 240a with the fourth surface 240b. The third surface 240a of the metal pattern 240 is in contact with the upper surface of the first insulating layer 211.

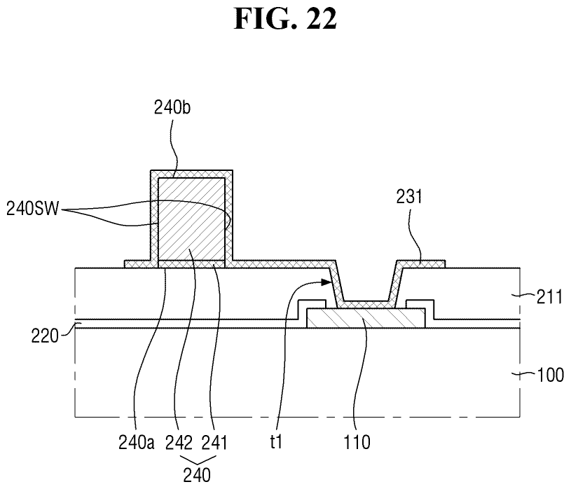

Referring to FIG. 22, the redistribution seed layer 231 may be formed. The redistribution seed layer 231 may extend along the sidewalls 240SW of the metal pattern 240, the fourth surface 240b of the metal pattern 240, and the sidewalls and the bottom surface of the first trench t1. The redistribution seed layer 231 may be also disposed on a portion of the upper surface of the first insulating layer 211. The redistribution seed layer 231 may be in contact with the exposed chip pad 110.

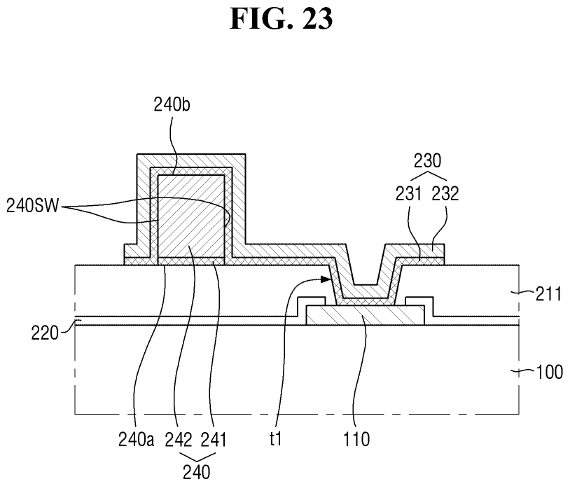

Referring to FIG. 23, the redistribution filling layer 232 may be formed. The redistribution filling layer 232 may be formed on the redistribution seed layer 231. The redistribution filling layer 232 may be formed using the redistribution seed layer 231 as a seed layer. The redistribution filling layer 232 and the redistribution seed layer 231 may constitute the redistribution pattern 230.

The redistribution pattern 230 may completely cover the sidewalls 240SW and the fourth surface 240b of the metal pattern 240. The redistribution pattern 230 may be in contact with the sidewalls 240SW of the metal pattern 240. However, the redistribution pattern 230 is not in contact with the third surface 240a of the metal pattern 240.

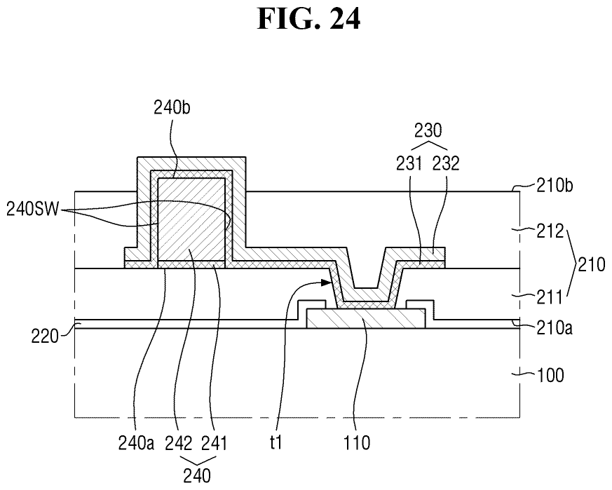

Referring to FIG. 24, the second insulating layer 212 may be formed. The second insulating layer 212 may be disposed on the first insulating layer 211. The second insulating layer 212 is disposed on the first insulating layer 211 based on the semiconductor chip 100. The first insulating layer 211 and the second insulating layer 212 may constitute the redistribution substrate 210. The redistribution substrate 210 includes a first surface 210a and a second surface 210b, which are opposite to each other. The first surface 210a may face the semiconductor chip 100.

The second surface 210b of the redistribution substrate 210 does not overlap the fourth surface 240b of the metal pattern 240 in a vertical direction, i.e., D1 direction. The vertical direction may be a direction orthogonal to the first surface 210a.

The metal pattern 240 may protrude from the second surface 210b of the redistribution substrate 210. The metal pattern 240 is not disposed on the second surface 210b of the redistribution substrate 210. As the metal pattern 240 is not disposed on the second surface 210b of the redistribution substrate 210, damage caused by a difference in coefficient of thermal expansion (CTE) between the metal pattern 240 and the second insulating layer 212 may be reduced. Therefore, the semiconductor package with improved reliability may be manufactured.

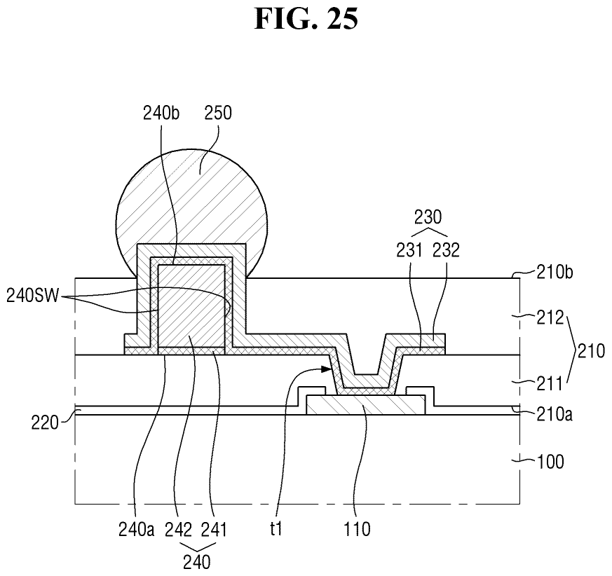

Referring to FIG. 25, the connection terminal 250 may be formed on the metal pattern 240. The connection terminal 250 may be directly in contact with the redistribution pattern 230, but embodiments of the present disclosure are not limited thereto.

In concluding the detailed description, those skilled in the art will appreciate that many variations and modifications may be made to the example embodiments without substantially departing from the principles of the present disclosure. Therefore, the disclosed example embodiments of the disclosure are used in a generic and descriptive sense only and not for purposes of limitation.

What is claimed is:

1. A semiconductor package comprising:
a redistribution substrate including a first surface and a second surface, which are opposite to each other in a first direction;
a semiconductor chip mounted on the first surface of the redistribution substrate;
a redistribution pattern in the redistribution substrate and electrically connected to the semiconductor chip;
a metal pattern electrically connected to the redistribution pattern, including a third surface and a fourth surface, which are opposite to each other in the first direction; and
a connection terminal on the second surface of the redistribution substrate and being in contact with the fourth surface of the metal pattern,
wherein at least a portion of the redistribution pattern is in contact with sidewalls of the metal pattern,
wherein the third surface faces the semiconductor chip and is not in contact with the redistribution pattern, and
wherein the fourth surface does not overlap the second surface in the first direction.

2. The semiconductor package of claim 1, wherein a first distance in the first direction from the first surface to the second surface is less than a second distance in the first direction from the first surface to the fourth surface.

3. The semiconductor package of claim 1, wherein the second surface and the fourth surface are coplanar.

4. The semiconductor package of claim 1, wherein the redistribution pattern completely covers the sidewalls and the fourth surface of the metal pattern.

5. The semiconductor package of claim 1, wherein the semiconductor chip includes a chip pad on a lower surface of the semiconductor chip,
wherein the redistribution substrate includes a first insulating layer including a trench, such that the chip pad is free of the first insulating layer, and a second insulating layer on the first insulating layer, and
wherein the redistribution pattern is disposed in the trench and electrically connected to the chip pad.

6. The semiconductor package of claim 5, wherein the third surface of the metal pattern is in contact with the first insulating layer.

7. The semiconductor package of claim 1, wherein sidewalls of the semiconductor chip and sidewalls of the redistribution substrate are aligned with each other.

8. The semiconductor package of claim 1, wherein the redistribution substrate is not in contact with the sidewalls and the fourth surface of the metal pattern.

9. The semiconductor package of claim 1, wherein a width of the redistribution substrate in a second direction intersecting the first direction is greater than a width of the semiconductor chip in the second direction.

10. A semiconductor package comprising:
a redistribution substrate including a first insulating layer and a second insulating layer, which are stacked in a first direction, the redistribution substrate including a first surface and a second surface, which are opposite to each other in the first direction;
a semiconductor chip mounted on the first surface of the redistribution substrate;
a redistribution pattern in the redistribution substrate;
a metal pattern at least partially in the first insulating layer and electrically connected to the redistribution pattern; and
a connection terminal on the first surface of the redistribution substrate, having one end electrically connected to the metal pattern and the other end electrically connected to the semiconductor chip,
wherein at least a portion of the redistribution pattern is in contact with sidewalls of the metal pattern,
wherein the metal pattern is not in contact with the first surface,
wherein a portion of the redistribution pattern overlaps the first insulating layer in a second direction crossing the first direction, and another portion of the redistribution pattern is on the first insulating layer, and
wherein a portion of the metal pattern is in contact with the second insulating layer.

11. The semiconductor package of claim 10, wherein at least a portion of the metal pattern protrudes from the first surface.

12. The semiconductor package of claim 10, wherein the metal pattern includes a pattern seed layer and a pattern filling layer on the pattern seed layer, and
wherein the pattern seed layer is in contact with the second insulating layer.

13. The semiconductor package of claim 10, wherein the redistribution pattern includes a redistribution seed layer and a redistribution filling layer on the redistribution seed layer, and
wherein the redistribution seed layer extends along the sidewalls and an upper surface of the metal pattern.

14. The semiconductor package of claim 10, wherein a width of the redistribution substrate in the second direction is the same as a width of the semiconductor chip in the second direction.

15. The semiconductor package of claim 10, wherein at least a portion of the first surface of the redistribution substrate does not overlap the semiconductor chip in the first direction.

16. The semiconductor package of claim 10, wherein the first insulating layer at least partially covers a portion of an upper surface of the metal pattern.

17. A semiconductor package comprising:
a semiconductor chip including a chip pad;
a first insulating layer including a trench, such that the chip pad is free of the first insulating layer, on the semiconductor chip;
a second insulating layer on the first insulating layer;
a metal pattern that passes through the second insulating layer and is in contact with the first insulating layer;
a redistribution pattern that extends along an upper surface of the first insulating layer, a profile of the metal pattern, and a profile of the trench and is electrically connected to the chip pad; and
a connection terminal, which is electrically connected to the metal pattern,
wherein the metal pattern protrudes from an upper surface of the second insulating layer.

18. The semiconductor package of claim 17, wherein the metal pattern includes a pattern seed layer that is in contact with the first insulating layer and a pattern filling layer on the pattern seed layer, and
wherein the redistribution pattern includes a redistribution seed layer that is in contact with the first insulating layer, the profile of the metal pattern and the chip pad, and a redistribution filling layer on the redistribution seed layer.

19. The semiconductor package of claim 17, wherein the metal pattern does not overlap the second insulating layer in a direction orthogonal to a surface of the second insulating layer.

20. The semiconductor package of claim 17, wherein a width of the first insulating layer and a width of the semiconductor chip are the same as each other.
